(19) United States
(12) Patent Application Publication
(10) Pub. No.: US 2013/0146837 A1
(43) Pub. Date: Jun. 13, 2013

(54) LIGHT EMITTING DIODE WITH MULTIPLE TRANSPARENT CONDUCTIVE LAYERS AND METHOD FOR MANUFACTURING THE SAME

(71) Applicants: CHIA-HUI SHEN, Hukou (TW); TZU-CHIEN HUNG, Hukou (TW)

(72) Inventors: CHIA-HUI SHEN, Hukou (TW); TZU-CHIEN HUNG, Hukou (TW)

(73) Assignee: ADVANCED OPTOELECTRONIC TECHNOLOGY, INC., Hsinchu Hsien (TW)

(21) Appl. No.: 13/563,756

(22) Filed: Aug. 1, 2012

(30) Foreign Application Priority Data
Dec. 12, 2011 (CN) 201110411758.0

(51) Int. Cl. H01L 33/42; H01L 33/06

(52) U.S. Cl. 257/13; 438/22; 257/E33.064

(57) ABSTRACT

An LED includes a first semiconductor layer, a second semiconductor layer, an active layer, a first transparent conductive layer, and a second transparent conductive layer. The first transparent conductive layer is formed on the second semiconductor layer. The second transparent conductive layer is formed on the first transparent conductive layer. The thickness of the first transparent conductive layer is less than that of the second transparent conductive layer. The density of the first transparent conductive layer is larger than that of the second transparent conductive layer. The disclosure further includes a method for manufacturing the LED.

### BACKGROUND

1. Technical Field

The disclosure relates to light emitting diodes, and particularly to a light emitting diode with multiple transparent conductive layers and a method for manufacturing the light emitting diode.

2. Description of the Related Art

A conventional light emitting diode (LED) includes a substrate, a light emitting structure having an N-type semiconductor layer, an active layer and a P-type semiconductor layer formed on the substrate in sequence, and two electrodes (i.e., N-type and P-type electrodes) respectively connected to the N-type and P-type semiconductor layers. To obtain an even current distribution in the semiconductor layers while do not lower the light extraction efficiency, a transparent conductive layer which is made of indium tin oxide (ITO) is formed on the light emitting structure.

The transparent conductive layer is required to have a relatively high electrical property and a relatively short manufacturing time. The electrical property of the transparent conductive layer varies along with different parameters for forming the transparent conductive layer. The higher the density of the transparent conductive layer is, the better the electrical property but the longer the manufacturing time of the transparent conductive layer is required. In contrast, the lower the density of the transparent conductive layer is, the shorter the manufacturing time required, but the poorer the electrical property of the transparent conductive layer is.

Therefore, it is desirable to provide a light emitting diode and a method for manufacturing a light emitting diode with both good electrical property and relatively short manufacturing time.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting diode and a method for manufacturing the light emitting diode. Moreover, in the drawings, like reference numerals designate corresponding parts throughout the views.

FIG. 1 is a cross-sectional view of a light emitting diode in accordance with one embodiment of the present disclosure.

FIG. 2 is a flow chart showing steps of a method for manufacturing the light emitting diode of FIG. 1.

### DETAILED DESCRIPTION

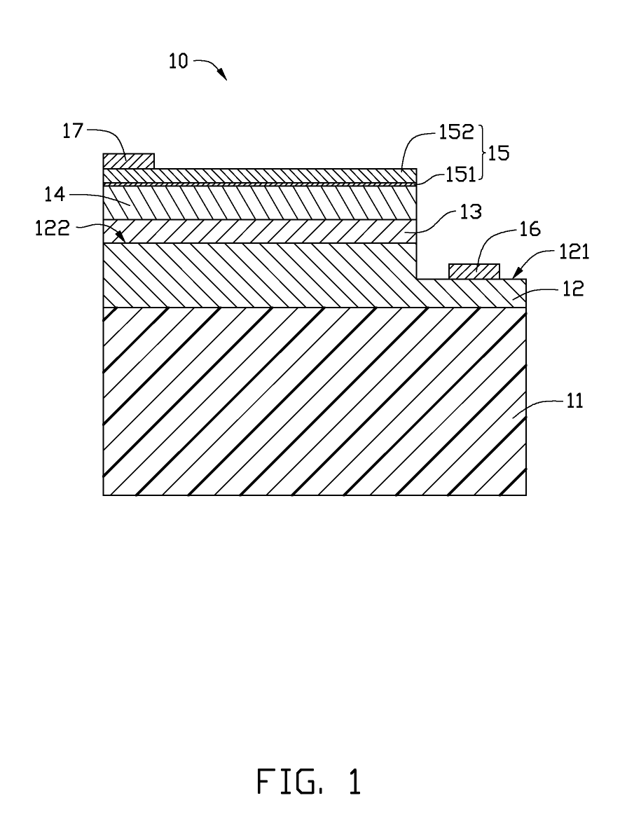

Referring to FIG. 1, a light emitting diode 10 in accordance with one embodiment is provided. The light emitting diode 10 includes a substrate 11, a light emitting structure, a transparent conductive layer 15 formed on the light emitting structure, a first electrode 16, and a second electrode 17 having an opposite polarity with respect to the first electrode 16. In this embodiment, the light emitting structure includes a first-type semiconductor layer 12, an active layer 13 and a second-type semiconductor layer 14. The transparent conductive layer 15 is transparent to light and conductive to electricity. When a bias is applied to the first and second electrodes 16, 17, electron holes and electrons flow from the first-type semiconductor layer 12 and the second-type semiconductor layer 14 to recombine at the active layer 13, whereby light is emitted from the active layer 13.

The substrate 11 is dielectric. The substrate 11 can be sapphire (α-Al₂O₃) substrate, silicon carbide (SiC) substrate, etc.

The first-type semiconductor layer 12, the active layer 13, the second-type semiconductor layer 14, and the transparent conductive layer 15 are formed on the substrate 11 in sequence from bottom to top. In other words, the first-type semiconductor layer 12 is formed on the substrate 11 directly. The active layer 13 is sandwiched between the first-type semiconductor layer 12 and the second-type semiconductor layer 14. The first-type semiconductor layer 12, the active layer 13 and the second-type semiconductor layer 14 can be made of III-V or II-VI compound semiconductors. The first-type semiconductor layer 12 and the second-type semiconductor layer 14 are doped with different materials. In this embodiment, the first-type semiconductor layer 12 is N-type doped, and the second-type semiconductor layer 14 is P-type doped. In alternative embodiment, the first-type semiconductor layer 12 can be P-type doped, and the second-type semiconductor layer 14 can be N-type doped.

The first-type semiconductor layer 12 includes an exposed first area 121 and a covered second area 122 both far away from the substrate 11. The exposed first area 121 of the first-type semiconductor layer 12 is formed by inductively coupled plasma dry etching. The first area 121 is positioned at a lateral end of the first-type semiconductor 12 and is uncovered by the active layer 13 and the second-type semiconductor layer 14. The second area 122 is covered by the active layer 13 and the second-type semiconductor layer 14.

The active layer 13 can be a single quantum well (SQW) structure or a multiple quantum well (MQW) structure.

The transparent conductive layer 15 is formed on the second-semiconductor layer 14 by vapor plating method. The transparent conductive layer 15 includes a first transparent conductive layer 151 and a second transparent conductive layer 152. The first and second transparent conductive layers 151, 152 are both made of ITO and accordingly are both ITO layers. The first transparent conductive layer 151 is directly grown on the second-type semiconductor layer 14, and the second transparent conductive layer 152 is grown on the first transparent conductive layer 151. A thickness of the first transparent conductive layer 151 is less than that of the second transparent conductive layer 152. The thickness of the first transparent conductive layer 151 is less than 600 angstroms. The thickness of the second transparent conductive layer 152 ranges from 1000 angstroms to 5000 angstroms. Vapor plating parameters for forming the first transparent conductive layer 151 and the second transparent conductive layer 152 are different. The density of the first transparent conductive layer 151 is larger than that of the second transparent conductive layer 152.

The first electrode 16 is formed on the first area 121 of the first-type semiconductor layer 12. The second electrode 17 is formed on the second transparent conductive layer 152. The first electrode 16 has a same polarity as the first-type semiconductor layer 12, and the second electrode 17 has a same polarity as the second-type semiconductor layer 14.

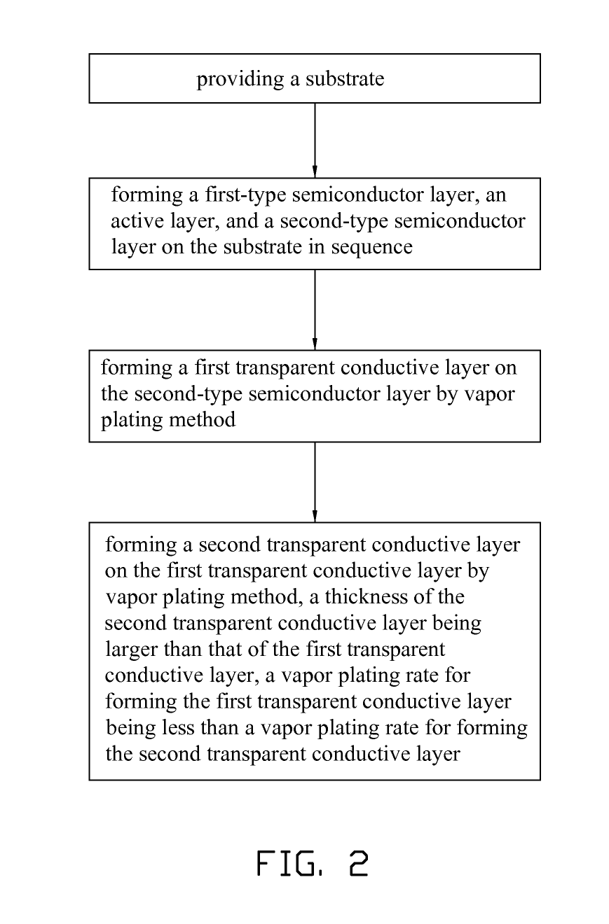

FIG. 2 shows a flow chart of a method for manufacturing the light emitting diode 10. The method for manufacturing the light emitting diode 10 includes the following steps.

Firstly, the substrate 11 is provided.

Secondly, the first-type semiconductor layer 12, the active layer 13, and the second-type semiconductor layer 14 are successively formed on the substrate 11. In this embodiment, the first-type semiconductor layer 12, the active layer 13, and the second-type semiconductor layer 14 can be successively formed on a sapphire substrate or a GaN substrate through a Metal Organic Chemical Vapor Deposition (MOCVD) equipment.

Thirdly, the first transparent conductive layer 151 is formed on the second-type semiconductor layer 14 by vapor plating method. The first transparent conductive layer 151 is formed by using a vapor plating rate less than 0.5 angstrom per second. The thickness of the first transparent conductive layer 151 is controlled in a range less than 600 angstroms. The lower the vapor plating rate for forming the first transparent conductive layer 151 is, the larger the density of the first transparent conductive layer 151.

Fourthly, the second transparent conductive layer 152 is formed on the first transparent conductive layer 151 by vapor plating method. The second transparent conductive layer 152 is formed by using a vapor plating rate more than 0.5 angstrom per second. The thickness of the second transparent conductive layer 152 is more than 1000 angstroms and less than 5000 angstroms.

A step of forming the first electrode 16 on the first area 121 of the first-type semiconductor 12 and a step of forming the second electrode 17 on the second transparent conductive layer 152 can be further provided after the step of forming the transparent conductive layer 15.

According to the disclosure, since the first transparent conductive layer 151 is formed with a relatively low vapor plating rate, the first transparent conductive layer 151 has an excellent electrical property. As such, the first transparent conductive layer 151 can be formed in ohmic contact with the second-type semiconductor layer 14 to drop a working voltage of the light emitting diode 10. In addition, a relatively small thickness of the first transparent conductive layer 151 can reduce its manufacturing time as much as possible. Although the second transparent conductive layer 152 is formed with a relatively high vapor plating rate, the working voltage of the light emitting diode 10 will not be increased significantly, because the second transparent conductive layer 152 is formed in ohmic contact with the first transparent conductive layer 151. Furthermore, although the second transparent conductive layer 152 has a relatively large thickness, the manufacturing time for forming the second transparent conductive layer 152 is still relatively short, because the second transparent conductive layer 152 is formed with a relatively high vapor plating rate. Therefore, the light emitting diode 10 can have good electrical property and relatively short manufacturing time.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting diode, comprising:
a light emitting structure; and
a transparent conductive layer formed on the light emitting structure, the transparent conductive layer comprising a first transparent conductive layer on the light emitting structure and a second transparent conductive layer on the first transparent conductive layer;
wherein a thickness of the first transparent conductive layer is less than that of the second transparent conductive layer, and a density of the first transparent conductive layer is larger than that of the second transparent conductive layer.

2. The light emitting diode of claim 1, wherein the thickness of the first transparent conductive layer is less than 600 angstroms.

3. The light emitting diode of claim 2, wherein the thickness of the second transparent conductive layer ranges from 1000 angstroms to 5000 angstroms.

4. The light emitting diode of claim 1, wherein the light emitting structure comprises a first-type semiconductor layer, an active layer formed on the first-type semiconductor layer, and a second-type semiconductor layer formed on the active layer.

5. The light emitting diode of claim 4, further comprising a first electrode and a second electrode, wherein the first-type semiconductor layer comprises a first area and a second area, the first area being exposed outside, the second area being covered by the active layer, the first electrode is formed on the first area of the first-type semiconductor layer, and the second electrode is formed on the second transparent conductive layer.

6. The light emitting diode of claim 4, further comprising a substrate, wherein the first-type semiconductor, the active layer, the second-type semiconductor, and the transparent conductive layer are formed on the substrate in sequence.

7. The light emitting diode of claim 4, wherein the first-type semiconductor layer is an N-type semiconductor layer and the second-type semiconductor layer is a P-type semiconductor layer.

8. The light emitting diode of claim 4, wherein the active layer is a single quantum well structure or a multiple quantum well structure.

9. The light emitting diode of claim 1, wherein the transparent conductive layer is in ohmic contact with the second-type semiconductor layer.

10. A method for manufacturing a light emitting diode comprising steps:
providing a substrate;
forming a light emitting structure on the substrate;
forming a first transparent conductive layer on the light emitting structure by vapor plating method; and
forming a second transparent conductive layer on the first transparent conductive layer by vapor plating method, a thickness of the second transparent conductive layer being larger than that of the first transparent conductive layer, a vapor plating rate for forming the first transparent conductive layer being less than a vapor plating rate for forming the second transparent conductive layer.

11. The method for manufacturing a light emitting diode of claim 10, wherein the first transparent conductive layer is formed by using a vapor plating rate less than 0.5 angstrom per second.

12. The method for manufacturing a light emitting diode of claim 11, wherein a thickness of the first transparent conductive layer is less than 600 angstroms.

13. The method for manufacturing a light emitting diode of claim 10, wherein the second transparent conductive layer is formed by using a vapor plating rate larger than 0.5 angstrom per second.

14. The method for manufacturing a light emitting diode of claim 13, wherein a thickness of the second transparent conductive layer ranges from 1000 angstroms to 5000 angstroms.

15. The method for manufacturing a light emitting diode of claim 10, wherein the light emitting structure comprises a first-type semiconductor layer, an active layer formed on the first-type semiconductor layer, and a second-type semiconductor layer formed on the active layer.

16. The method for manufacturing a light emitting diode of claim 15, wherein the first-type semiconductor layer comprises a first area and a second area, the first area being exposed outside, and the second area being covered by the active layer.

17. The method for manufacturing a light emitting diode of claim 16, further comprising a step of forming a first electrode on the first area of the first-type semiconductor and a step of forming a second electrode on the second transparent conductive layer after the step of forming the second transparent conductive layer.

18. The method for manufacturing a light emitting diode of claim 15, wherein the first-type semiconductor layer is an N-type semiconductor layer and the second-type semiconductor layer is a P-type semiconductor layer.
